(19) United States
(12) Patent Application Publication
(10) Pub. No.: US 2025/0132232 A1
(43) Pub. Date: Apr. 24, 2025

(54) ELECTRONIC DEVICE

(71) Applicant: Advanced Semiconductor Engineering, Inc., Kaohsiung (TW)

(72) Inventor: Jen-Hao PAN, Kaohsiung (TW)

(73) Assignee: Advanced Semiconductor Engineering, Inc., Kaohsiung (TW)

(21) Appl. No.: 18/490,615

(22) Filed: Oct. 19, 2023

(51) Int. Cl. H01L 23/495; H01L 21/48; H01L 21/56; H01L 25/065

(52) U.S. Cl. CPC H01L 23/49548; H01L 21/4825; H01L 21/565; H01L 23/4951; H01L 25/0657

(57) ABSTRACT

An electronic device is provided. The electronic device includes a first circuit structure, a second circuit structure, a conductive layer, and a supporting structure. The conductive layer is disposed between the first circuit structure and the second circuit structure. The supporting structure is at least partially covered by the conductive layer and defines a space configured to vent gas

### BACKGROUND

### 1. Field of the Disclosure

The present disclosure relates to an electronic device and, in particular, an electronic device including a supporting structure.

### 2. Description of the Related Art

In packaging, devices may be stacked and electrically connected through a conductive material. As the devices increase in weight, the distances therebetween can reduce, generating difficulty in formation of the conductive material.

### SUMMARY

In some embodiments, an electronic device includes a first circuit structure, a second circuit structure, a conductive layer, and a supporting structure. The conductive layer is disposed between the first circuit structure and the second circuit structure. The supporting structure is at least partially covered by the conductive layer and defines a space configured to vent gas.

In some embodiments, an electronic device includes a first pad, a second pad, and a plurality of first conductive structures. The second pad is disposed over the first pad. The plurality of first conductive structures extend from the first pad and toward the second pad. At least one of the plurality of first conductive structures has a height greater than a distance between the at least one of the plurality of first conductive structures and the second pad.

In some embodiments, an electronic device includes a first pad, a supporting element, and a second pad. The first pad has a first center. The supporting element is connected to the first pad and has a second center non-overlapping with the first center. The second pad is supported by the supporting element and electrically connected to the first pad.

### BRIEF DESCRIPTION OF THE DRAWINGS

Aspects of some embodiments of the present disclosure are readily understood from following detailed description when read with the accompanying figures. It is noted that various structures may not be drawn to scale, and dimensions of the various structures may be arbitrarily increased or reduced for clarity of discussion.

FIG. 1 is a cross-section of an electronic device according to some embodiments of the present disclosure.

FIG. 1A is an enlarged view of the box 1A in FIG. 1.

FIG. 1B is a top view along the line 1B-1B′ in FIG. 1A.

FIG. 2 is a cross-section of an electronic device according to some embodiments of the present disclosure.

FIG. 3 is a cross-section of an electronic device according to some embodiments of the present disclosure.

FIG. 3A is an enlarged view of the box 3A in FIG. 3.

FIG. 3B are top views of the line 3B-3B′ in FIG. 3A during a formation of a conductive layer according to some embodiments of the present disclosure.

FIG. 3C is another top view of the box 3A in FIG. 3.

FIG. 3D is a top view of the line 3D-3D′ in FIG. 3C during a formation of a conductive layer according to some embodiments of the present disclosure.

FIG. 3E is another top view of the box 3A in FIG. 3.

FIG. 3F is another top view of the box 3A in FIG. 3.

FIG. 4 is a cross-section of an electronic device according to some embodiments of the present disclosure.

FIG. 5 is a top view of a pad of an electronic device according to some embodiments of the present disclosure.

FIGS. 5A, 5B, 5C, and 5D each illustrate the arrangement of a plurality of conductive structures in a portion of a pad of the electronic device according to some embodiments of the present disclosure.

FIG. 6 is a cross-section of an electronic device according to some embodiments of the present disclosure.

FIG. 6A is an enlarged view of the box 6A in FIG. 6.

FIG. 6B is a top view of the line 6B-6B′ in FIG. 6A according to some embodiments of the present disclosure.

FIGS. 6C and 6D are another top view of the line 6B-6B′ in FIG. 6A according to some embodiments of the present disclosure.

FIG. 7A is another top view of the box 6A in FIG. 6.

FIG. 7B is another top view of the box 6A in FIG. 6.

FIG. 8 is a cross-section of an electronic device according to some embodiments of the present disclosure.

FIG. 8A is an enlarged view of the box 8A in FIG. 8.

FIG. 8B is a top view of the line 8B-8B′ in FIG. 8A according to some embodiments of the present disclosure.

FIGS. 8C, 8D, 8E, and 8F are each another top view of the line 8B-8B′ in FIG. 8A according to some embodiments of the present disclosure.

FIG. 9 is a cross-section of an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

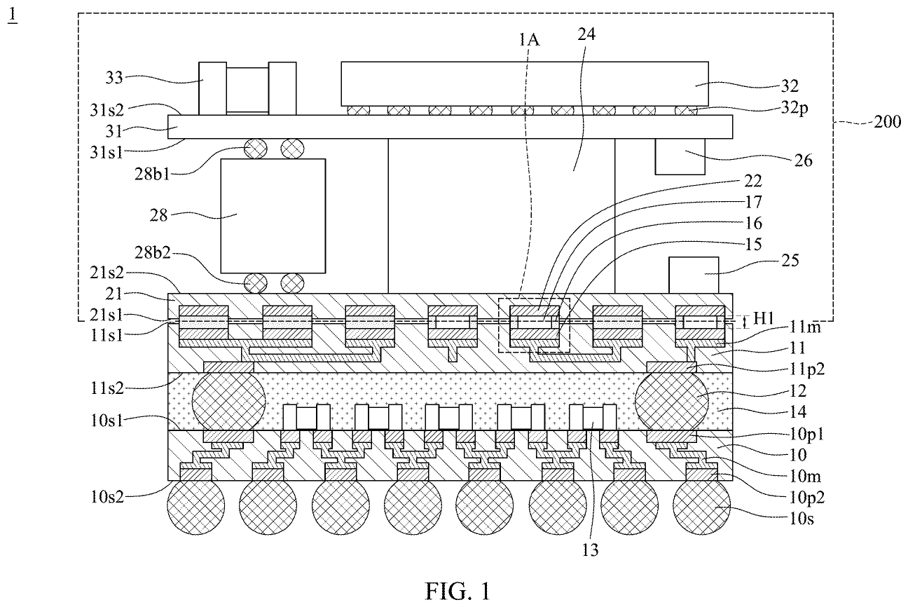

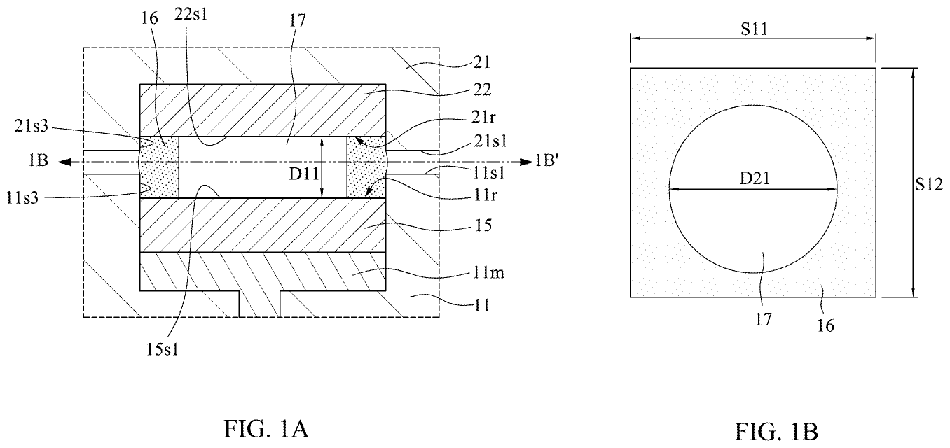

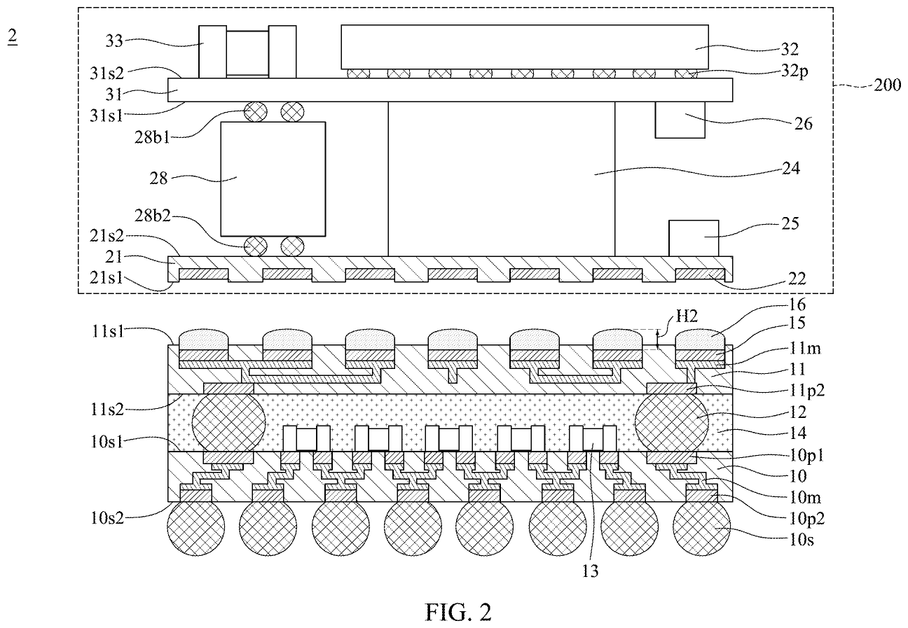

FIG. 1 is a cross-section of an electronic device 1 according to some embodiments of the present disclosure. The electronic device 1 includes a circuit structure 10, a circuit structure 11, a circuit structure 21, a circuit structure 31, a plurality of electrical elements 12, a plurality of electronic components 13, an encapsulant 14, a pad 15, a conductive layer 16, a second pad 22, an electronic component 24, a plurality of electronic components 25, 26, an interposer 28, a semiconductor die 32, and an electronic component 33.

The circuit structure (or a carrier, a substrate) 10 is disposed under the circuit structure 11. The circuit structure 10 has a first surface 10s1 and a second surface 10s2 opposite thereto. In some embodiments, the circuit structure 10 may include an interposer. In some embodiments, the circuit structure 10 may include, for example, a printed circuit board (PCB), such as a paper-based copper foil laminate, a composite copper foil laminate, or a polymer-impregnated glass-fiber-based copper foil laminate. In some embodiments, the circuit structure 10 may include a semiconductor substrate including silicon, germanium, or other suitable materials. The circuit structure 10 may be referred as a carrier, or substrate.

The circuit structure 10 may include a plurality of pads 10p1 disposed at the first surface 10s1 and a plurality of pads 10p2 disposed at the second surface 10s2. The pads 10p1 may be electrically connected to the plurality of electrical elements 12 and/or the plurality of electronic components 13. The pads 10p2 may be electrically connected to a plurality of solder balls 10s, which may be connected to an external device, system, or circuit board. The circuit structure 10 may include a redistribution layer (RDL) or traces 10m disposed between the pads 10p1 and 10p2. The pads 10p1 may be electrically connected to the pads 10p2 through the traces 10m. In some embodiments, the circuit structure 10 may include dielectric material that surrounds the pads 10p1, 10p2, and the traces 10m.

The pads 10p1, 10p2, and the traces 10m may be formed of metal or a metal alloy. The pads 10p1, 10p2, and the traces 10m may be metal, such as copper, gold, silver, aluminum, titanium, tantalum, or the like. The solder balls 10s may include controlled collapse chip connection (C4) bumps, a ball grid array (BGA), or a land grid array (LGA).

The electronic components 13 may be electrically connected to the electronic components 25, 26 through the electrical elements 12. The electrical elements 12 may include solder balls. The electronic components 13 may be disposed between the circuit structure 10 and the circuit structure 11. The electronic components 13 may include a passive device, such as, a capacitor, an inductor, and/or a resistor. The electronic components 13 may include an active device, such as a transistor, or the like. The encapsulant 14 may cover the electronic components 13 and the electrical elements 12. In some embodiments, the encapsulant 14 may include an epoxy resin including fillers, a molding compound (e.g., an epoxy molding compound or another molding compound), polyimide, a phenolic compound or material, a material including silicone dispersed therein, or a combination thereof.

The circuit structure (or a carrier, a substrate) 11 is disposed below the electronic component 24. The circuit structure 11 is disposed under the circuit structure 21. The circuit structure 11 has a first surface 11s1 and a second surface 11s2 opposite thereto. The first surface 11s1 of the circuit structure 11 faces the circuit structure 21, while the second surface 11s2 of the circuit structure 11 faces away from the circuit structure 21. The second surface 11s2 faces the first surface 10s1. In some embodiments, the circuit structure 11 may include an interposer. In some embodiments, the circuit structure 11 may include, for example, a printed circuit board (PCB), such as a paper-based copper foil laminate, a composite copper foil laminate, or a polymer-impregnated glass-fiber-based copper foil laminate. In some embodiments, the circuit structure 11 may include a semiconductor substrate including silicon, germanium, or other suitable materials. The circuit structure 11 may be referred as a carrier, or substrate.

The circuit structure 11 may include the plurality of pads 15 disposed at the first surface 11s1 and a plurality of pads 11p2 disposed at the second surface 11s2. The pads 15 may be electrically connected to the circuit structure 21 or the plurality of pads 22 through the conductive layer 16. The pads 11p2 may be electrically connected to the plurality of electrical elements 12, which may be connected to the circuit structure 10. The circuit structure 11 may include a redistribution layer (RDL) or traces 11m disposed between the pads 15 and 11p2. The pads 15 may be electrically connected to the pads 11p2 through the traces 11m. In some embodiments, the circuit structure 11 may include dielectric material that surrounds the pads 15, 11p2, and the traces 11m.

The pads 15, 11p2, and the traces 11m may be formed of metal or a metal alloy. The pads 15, 11p2, and the traces 11m may be metal, such as copper, gold, silver, aluminum, titanium, tantalum, or the like.

The circuit structure (or a carrier, a substrate) 21 is disposed below the circuit structure 31, the electronic component 24, and the electronic component 25, 26. The circuit structure 21 is disposed above the circuit structure 11. The circuit structure 21 has a first surface 21s1 and a second surface 21s2 opposite thereto. The first surface 21s1 of the circuit structure 21 faces the circuit structure 11, while the second surface 21s2 of the circuit structure 21 faces away from the circuit structure 11. The second surface 21s2 faces the circuit structure 31. In some embodiments, the circuit structure 21 may include an interposer. In some embodiments, the circuit structure 21 may include, for example, a printed circuit board (PCB), such as a paper-based copper foil laminate, a composite copper foil laminate, or a polymer-impregnated glass-fiber-based copper foil laminate. In some embodiments, the circuit structure 21 may include a semiconductor substrate including silicon, germanium, or other suitable materials. The circuit structure 21 may be referred as a carrier, or substrate.

The circuit structure 21 may include the plurality of pads 22 disposed at the first surface 21s1 and a plurality of pads (not shown) disposed at the second surface 21s2. The pads 22 may be electrically connected to the plurality of pads 15 through the conductive layer 16. In other words, the circuit structure 11 is electrically connected to the circuit structure 21. The pads at the second surface 21s2 may be electrically connected to the electronic component 24 and the electronic component 25. The circuit structure 21 may include a redistribution layer (RDL) or traces (not shown) disposed between the pads 22 and the second surface 21s2. The pads 22 may be electrically connected to the pads at the second surface 21s2 through the traces of the circuit structure 21. In some embodiments, the circuit structure 21 may include dielectric material that surrounds the pads 22, the pads at the second surface 21s2, and the traces of the circuit structure 21.

The pads 22 may be formed of metal or a metal alloy. The pads 22 may be metal, such as copper, gold, silver, aluminum, titanium, tantalum, or the like. The pad 22 may be disposed over the pad 15. The conductive layer 16 may be disposed between the pads 15 and 22 or between the circuit structures 11 and 21. The conductive layer 16 may be connected to the first pad and the second pad. The conductive layer may cover the pad 15 or the pad 22. The conductive layer 16 may be referred to as an adhesive layer, or an adhesive conductive layer, or a connection element. The conductive layer 16 may include a solder paste. The conductive layer 16 may be tin paste, copper paste, silver paste, or the like. The conductive layer 16 may have a height H1 perpendicular to the first surface 11s1 of the circuit structure 11. In some embodiments, the height H1 may be defined as a distance between the pads 22 and the pads 15.

The electronic component 24 and the electronic component 25 are disposed over the circuit structure 21. The electronic component 24 and the electronic component 25 are disposed between the circuit structure 21 and the circuit structure 31. The electronic component 24 may be disposed adjacent to the electronic component 25. In some embodiments, the electronic component 24 may be surrounded by the electronic component 25. The electronic component 25 may include a passive device, such as, a capacitor, an inductor, and/or a resistor. The electronic component 25 may include an active device, such as a transistor, or the like. The electronic component 25 may include an integrated circuit (IC). The electronic component 25 may be electrically connected to the electronic component 24 through the circuit structure 21.

The interposer 28 may be connected to the circuit structure 31 through a plurality of solder balls 28b1. The interposer 28 may be connected to the circuit structure 21 through a plurality of solder balls 28b2. The circuit structure 21 may be (electrically) connected to the circuit structure 31 through the interposer 28. The interposer 28 may be disposed between the circuit structure 31 and the circuit structure 21. The interposer 28 may be disposed adjacent to the electronic component 24. The interposer 28 may be referred to as an interconnection structure. The interposer 28 may include a plurality of circuit layers embedded in dielectric material and electrically connected to the circuit structure 31 and/or the circuit structure 21.

The electronic component 24 may be configured to provide power to the electronic components 13, the electronic component 25, the electronic component 26, the semiconductor die 32, and/or the electronic component 33. The electronic component 24 may provide different power signals (e.g., voltage or current) that are respectively applicable to the above elements. The electronic component 24 may be configured to convert a power signal from an external power source to a plurality of varied power signals. The electronic component 24 may include a monolithic power system.

The electronic component 24 has a weight, a volume, a size in Z-height, or a surface area contacting the surface 21s2 of the circuit structure greater than that of each of the electronic components 25 and 26. For example, the weight of the electronic component 24 may be 100 times of that of each of the electronic component 25. The electronic component 24 disposed over the second surface 21s2 of the circuit structure 21. The electronic component 24 may be disposed directly above a group of the pads 22 the circuit structure 21 and/or the pads 15 of the circuit structure 11. The electronic component 25 may be disposed directly above another group of the pads 22 of the circuit structure 21.

The electronic device 1 may include a power module (or a package structure) 200 including the circuit structure 21, the electronic component 24, the electronic components 25, 26, the circuit structure 31, the semiconductor die 32 and the electronic component 33. The power module 200 may be configured to provide power to the electronic component 13 through the circuit structure 11. The power module 200 may be configured to provide power to other elements/devices/components through the circuit structure 10 and the circuit structure 11.

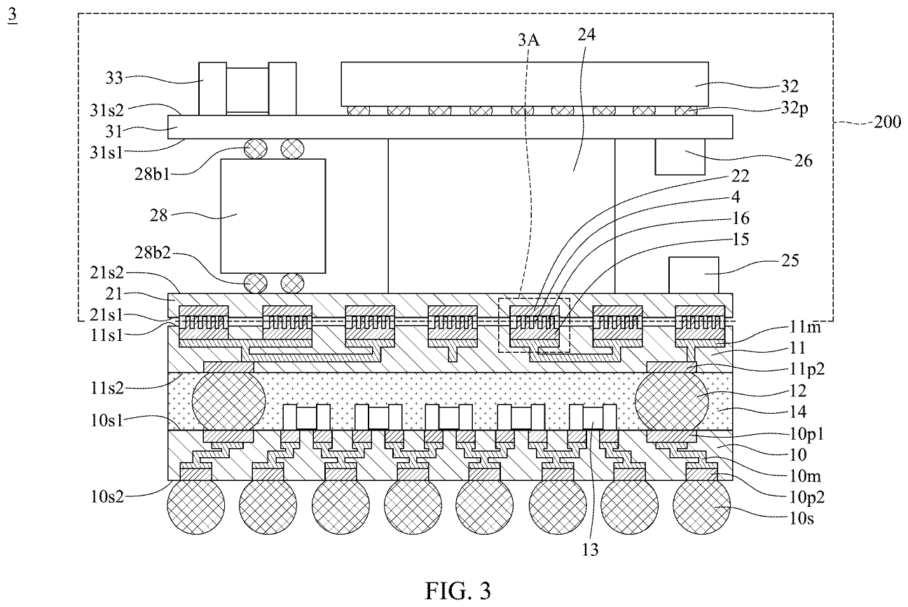

FIG. 2 is a cross-section of an electronic device 2 according to some embodiments of the present disclosure. The electronic device 2 in FIG. 2 is similar to the electronic device 1 in FIG. 1. Therefore, some detailed descriptions may refer to corresponding preceding paragraphs and are not repeated hereinafter for conciseness, with differences therebetween as follows.

FIG. 2 illustrates a stage prior to the power module 200 being connected to the circuit structure 11 through the conductive layer 16. The conductive layer 16 may have a height H2 that is greater than the height H1 in the conductive layer 16 since the conductive layer 16 has been pressed in the mounting process due to the weight of the power module 200 and flowed in a molten state in the reflow process. The reflow process makes the conductive layer 16 have properties with cohesion and adhesion to form the solder joints with the pads 22 and/or the pads 15. As such, the electrical connection between the pads 22 and 15 (or the circuit structure 21 and 11) can be established.

Prior to the reflow process, the conductive layer 16 may have gas (or air) which is normally vented during the reflow process. Owing to the power module 200 with the relatively heavy weight, a space between the circuit structure 21 and the circuit structure 11 for venting the gas may be significantly shortened during the reflow process for the conductive layer 16. The gas may not be completely exhausted during the reflow process and thus a void 17 may be formed. The void 17 may be surrounded by the conductive layer 16. FIG. 1A is an enlarged view of the box 1A in FIG. 1 that reveals the details around the conductive layer 16.

As shown in FIG. 1A, the void 17 is surrounded by the conductive layer 16. The pad 15 has a surface 15s1 facing the pad 22. The surface 15s1 is in contact with the conductive layer 16. The pad 22 has a surface 22s1 facing the pad 15. The surface 22s1 is in contact with the conductive layer 16. The surface 15s1 and the first surface 11s1 of the circuit structure 11 may be non-coplanar. The circuit structure 11 may have a recess 11r accommodating the pad 15. The recess 11r may have a sidewall 11s3 in contact with the conductive layer 16. The surface 22s1 and the first surface 21s1 of the circuit structure 21 may be non-coplanar. The circuit structure 21 may have a recess 21r accommodating the pad 22. The recess 21r may have a sidewall 21s3 in contact with the conductive layer 16. The surface 15s1 of the pad 15 and the surface 22s1 of the pad 22 define a distance D11 therebetween perpendicular to the surface 15s1 or 22s1.

A portion of the surface 15s1 of the pad 15 may be exposed to the void 17. The surface 15s1 may be in contact with the void 17. A portion of the surface 22s1 of the pad 22 may be exposed to the void 17. The surface 22s1 may be in contact with the void 17. The void 17 may be spaced apart from the sidewall 11s3 of the recess 11r by the conductive layer 16. The void 17 may be spaced apart from the sidewall 21s3 of the recess 21r by the conductive layer 16.

FIG. 1B is a top view along the line 1B-1B′ in FIG. 1A. The void 17 has a diameter (or size) D21. The conductive layer 16 has a length S11 and a width S12. The length S12 and the width S12 may be substantially the same or similar to the length and width of the pad 15. The void rate is defined by the ratio of the area of the void 17 to the area of the pad 15. In the electronic device 1, the void rate of the void 17 is around 50%. The void rate with such extent may impact the electrical connection between the pad 15 and the pad 22 (or between the circuit structures 21 and 11). The void 17 may have a high resistance that increases the equivalent resistance of the electrical connection between the pad 15 and the pad 22. The signal transmission speed may be adversely influenced. Furthermore, the relatively large void 17 would worsen the void explosion issue during the following thermal process.

Referring back to FIG. 1, the circuit structure (or a carrier, a substrate) 31 is disposed below the semiconductor die 32, the electronic component 33. The circuit structure 31 is disposed above the circuit structure 21 and the electronic component 24. The circuit structure 31 has a first surface 31s1 and a second surface 31s2 opposite thereto. The first surface 31s1 of the circuit structure 31 faces the circuit structure 21, while the second surface 31s2 of the circuit structure 31 faces away from the circuit structure 21. The first surface 31s1 faces the electronic component 24. The second surface 31s2 faces the semiconductor die 32. In some embodiments, the circuit structure 31 may include an interposer. In some embodiments, the circuit structure 31 may include, for example, a printed circuit board (PCB), such as a paper-based copper foil laminate, a composite copper foil laminate, or a polymer-impregnated glass-fiber-based copper foil laminate. In some embodiments, the circuit structure 31 may include a semiconductor substrate including silicon, germanium, or other suitable materials. The circuit structure 31 may be referred as a carrier, or substrate.

The electronic component 26 is disposed over the first surface 31s1 of the circuit structure 31. The electronic components 26 may be disposed between the circuit structure 21 and the circuit structure 31. The semiconductor die 32 and the electronic component 33 are disposed over the second surface 31s2 of the circuit structure 31. The semiconductor die 32 may include a plurality of solder balls 32p electrically connected to the circuit structure 31. The semiconductor die 32 may be electrically connected to the electronic component 24 through the circuit structure 31 (or the trace, pad (not shown) in the circuit structure 31). The electronic component 33 may be electrically connected to the electronic component 24 through the circuit structure 31 (or the trace, pad (not shown) in the circuit structure 31). The semiconductor die 32 may be disposed directly above the electronic component 24.

The electronic component 26 may include a passive device, such as a capacitor, an inductor, and/or a resistor. The electronic component 26 may include an active device, such as a transistor, or the like. The electronic component 26 may include an integrated circuit (IC). The electronic components 33 may include a passive device, such as, a capacitor, an inductor, and/or a resistor. The electronic components 33 may include an active device, such as a transistor, or the like. The semiconductor die 32 may include active components. The active components may be used to inject power into a circuit, and control or amplify signals, which may include time-varying voltage, current, electromagnetic waves, photons, or other signals. In some embodiments, the semiconductor die 32 may include a logic die (e.g., system-on-a-chip (SoC), central processing unit (CPU), graphics processing unit (GPU), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active components.

In some embodiments, an underfill or an encapsulant may be disposed between the circuit structure 11 and the circuit structure 21, or the circuit structure 21 and the circuit structure 31. In some embodiments, an encapsulant may be disposed over the circuit structure 31 and cover the semiconductor die 32 and the electronic component 33.

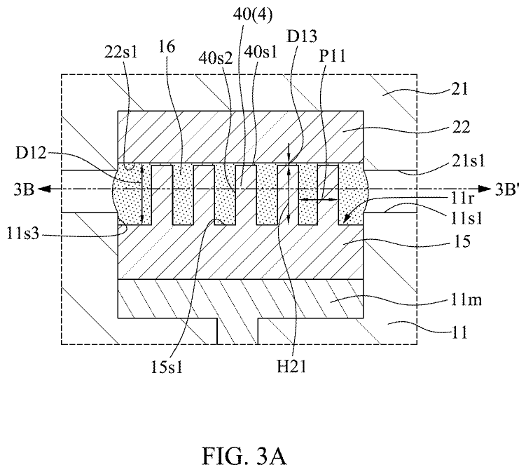

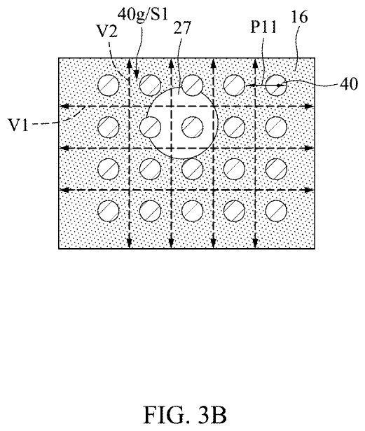

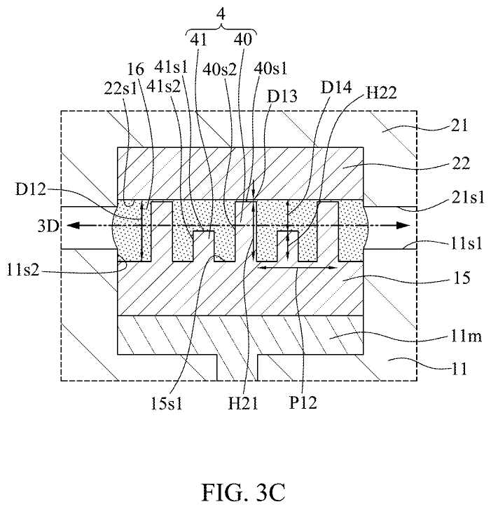

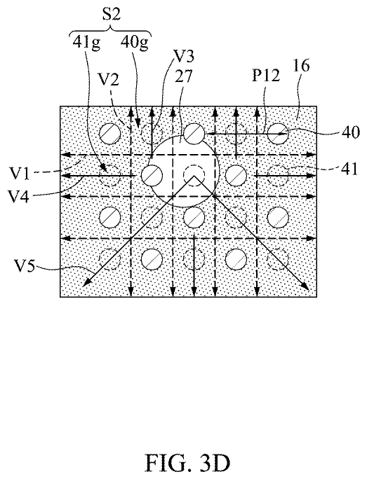

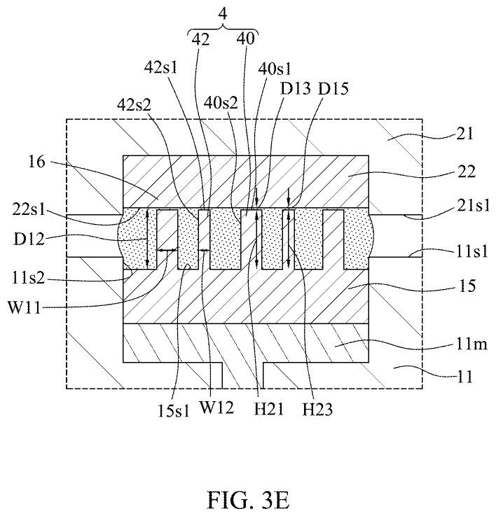

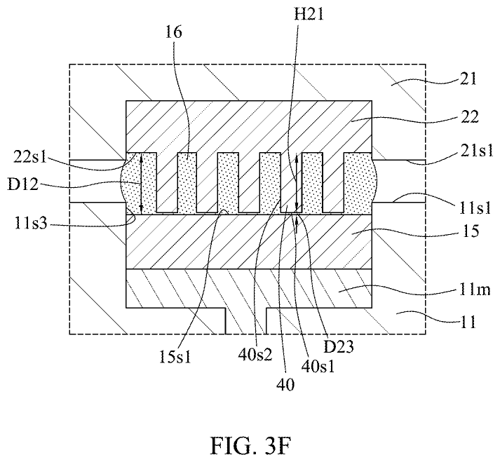

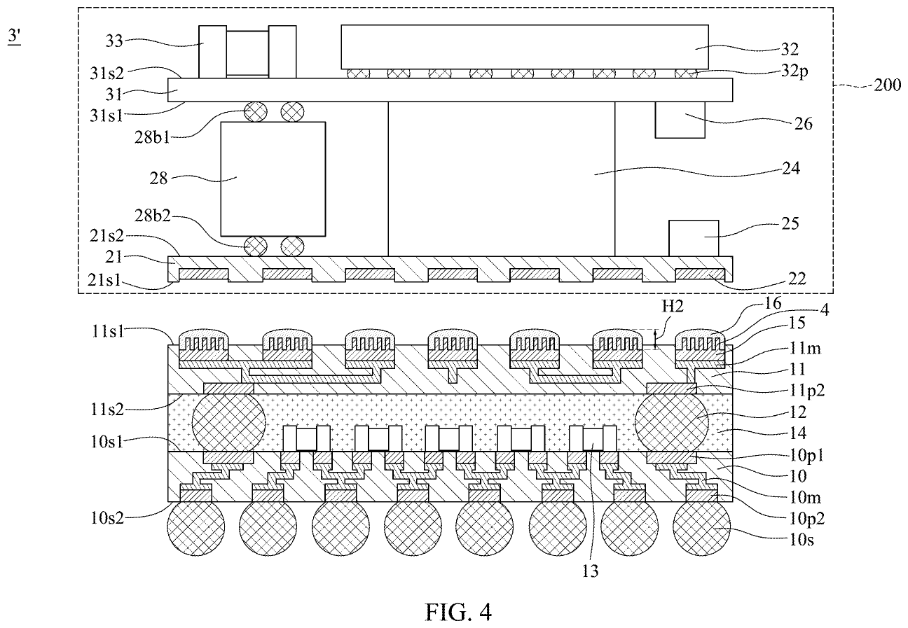

FIG. 3 is a cross-section of an electronic device 3 according to some embodiments of the present disclosure. The electronic device 3 in FIG. 3 is similar to the electronic device 1 in FIG. 1. Therefore, some detailed descriptions may refer to corresponding preceding paragraphs and are not repeated hereinafter for conciseness, with differences therebetween as follows.

The electronic device 3 includes a vent structure (or a supporting structure or a supporting element) 4 disposed over each of the pads 15. The vent structure 4 may be connected to at least one of the pads 15. In some embodiments, the vent structure 4 may be disposed over a group of the pads 15. In particular, the vent structure 4 may be disposed over a group of the pads 15 that is directly below the electronic component 24. The vent structure 4 is disposed over the first surface 11s1 of the circuit structure 11. The vent structure 4 is disposed over the first surface 21s1 of the circuit structure 21. The vent structure 4 may be at least partially covered by the conductive layer (or the adhesive layer) 16. The vent structure 4 may be configured to vent a gas from the conductive layer 16, e.g., during the reflow process thereof.

FIG. 3A is an enlarged view of the box 3A in FIG. 3 that reveals the details around the vent structure 4. The vent structure 4 may include a plurality of conductive structures (or a plurality of first conductive structures) 40. The conductive structures 40 may extend from the pad 15 and toward the pad 22. The conductive structures 40 may be disposed directly above the pad 15. The conductive structures 40 may be disposed directly below the pad 22. The conductive structures 40 is in contact with the pad 15. The conductive structures 40 are spaced apart from the sidewall 11s3 of the recess 11r and/or the sidewall 21s3 of the recess 21r. The conductive structures 40 may be covered, surrounded, or encapsulated by the conductive layer 16.

The conductive structures 40 may include a plurality of conductive pillars. The conductive structures 40 may be formed of metal or a metal alloy. The conductive structures 40 may be metal, such as copper, gold, silver, aluminum, titanium, tantalum, or the like. The electrical conductivity of the conductive structures 40 (or the vent structure 4) is greater than that of the conductive layer 16.

The conductive structures 40 of the vent structure 4 have a surface 40s1 facing the pad 22 (or the circuit structure 21). The surface 40s1 may face away from the pad 15 (or the circuit structure 11). The surface 40s1 of the conductive structures 40 is closer to the surface 22s1 of the pad 22 than the surface 15s1 of the pad 15. At least one of the conductive structures 40 of the vent structure 4 has a height H21 perpendicular to the surface 15s1 of the pad 15. The height H21 may be defined by the surface 40s1 of the conductive structures 40 and the surface 15s1 of the pad 15. The conductive structures 40 (or the vent structure 4) is spaced apart from the pad 22. The surface 40s1 is free from contacting the pad 22. The surface 40s1 may not contact the pad 22. A distance D13 is defined by the surface 40s1 and the surface 22s1 of the pad 22. The height H21 is greater than the distance D13 between the conductive structures 40 and the pad 22. The surface 40s1 may be covered by the conductive layer 16. In some embodiments, the surface 40s1 may be entirely covered by the conductive layer 16. The surface 40s1 may be in contact with the conductive layer 16. A portion of the conductive layer 16 may be disposed directly above the surface 40s1 or between the surface 40s1 and the surface 22s1. In some embodiments, the surface 40s1 of the conductive structure 40 (or the vent structure 4) may contact the surface 22s1 of the pad 22.

The conductive structures 40 of the vent structure 4 have a sidewall 40s2 extending perpendicular to the surface 15s1 of the pad 15. The sidewalls 40s2 of the conductive structures 40 are surrounded, covered, or encapsulated by the conductive layer 16. The sidewalls 40s2 of the conductive structures 40 are spaced apart from the sidewall 11s3 of the recess 11r.

The surface 15s1 of the pad 15 and the surface 22s1 of the pad 22 define a distance D12 therebetween perpendicular to the surface 15s1 or 22s1. The distance D12 may represent the height of the conductive layer 16. The distance D12 is greater than the height H21 of the conductive structures 40 (or vent structure 4). The height H21 is greater than a half of the distance D12. The distance D12 is greater than the distance D11 in FIG. 1A. In some embodiments, the distance D12 may be 40 μm, 45 μm, 50 μm, or more and the distance D11 may be less than 20 μm.

FIG. 3B is a top view of the line 3B-3B′ in FIG. 3A during the formation of the conductive layer (or the adhesive layer) 16 according to some embodiments of the present disclosure. FIG. 3B illustrates the reflow process of the conductive layer 16. The conductive structures 40 may be circular in a top view. In some embodiments, the conductive structures 40 may be rectangular, triangular, or oval in a top view.

The conductive layer 16 may have gas (or air) 27 when it is formed over the pads 15. The gas 27 may be surrounded by the conductive layer 16. The location of the gas 27 may be random. FIG. 3B illustrates an example in which the gas 27 is located in the center of the conductive layer 16. The conductive structures 40 (or the vent structure 4) may define a space S1 configured to vent the gas 27. The conductive structures 40 (or the vent structure 4) may define a plurality of vent paths V1 and V2 which are configured to vent the gas 27 of the conductive layer 16 during the reflow process. The vent paths V1 and V2 extend through the space S1 which includes a plurality of gaps 40g between the first conductive structures 40. The vent paths V1 may extend in a different direction from the vent paths V2. The gas 27 of the conductive layer is directed from a first vicinity of a center portion (or a center group) of the conductive structures 40 to a second vicinity of an edge portion (or an edge group) of the conductive structures 40.

In some embodiments, the conductive structures 40 have a pitch P11 defined by, for example, a distance between the leftmost end of one conductive structure and the leftmost end of the most adjacent conductive structure. As the pitch P11 is larger, the space S1 (or the gaps 40g) may be larger which can improve the vent capacity of the conductive structures 40. In some embodiments, the distance D13 is less than the pitch P11 of the conductive structures 40.

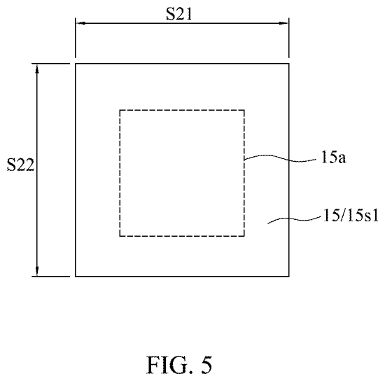

FIG. 4 is a cross-section of an electronic device 3′ according to some embodiments of the present disclosure. The electronic device 3′ in FIG. 4 is similar to the electronic device 3 in FIG. 3. Therefore, some detailed descriptions may refer to corresponding preceding paragraphs and are not repeated hereinafter for conciseness, with differences therebetween as follows.

FIG. 4 illustrates a stage prior to the circuit structure 21 being connected to the circuit structure 11 through the conductive layer 16. The vent structure 4 is covered by the conductive layer 16. The height H2 of the conductive layer 16 may be greater than the height H21 of the vent structure 4. The height H21 of the vent structure 4 may be around 50%, 55%, 60%, 65%, 70%, 75%, or 80% of the height H2 of the conductive layer 16. The reflow process makes the conductive layer 16 have properties with cohesion and adhesion to form the solder joints with the pads 22 and/or the pads 15. As such, the electrical connection between the pads 22 and 15 (or the circuit structure 21 and 11) can be established.

The conductive structures 40 of the vent structure 4 have the height H21 greater than the distance D13. The height H21 is greater than a half of the distance D12 between the pads 15 and 22. Furthermore, a surface area of all the conductive structures 40 is more than around 30% of that of the surface 15s1 of the pad 15 in a top view. The surface area of all the conductive structures 40 may be around 35%, 40%, 45%, 50% or more of that of the surface 15s1 of the pad 15 in a top view. With this design regarding the size and the surface area ratio, the vent structure 4 may be referred to as a supporting structure that is configured to support the relative heavy power module 200. The pad 22 may be supported by the supporting structure 4, e.g., through the portion of conductive layer 16 therebetween. The supporting structure 4 can provide additional support for the power module 200. The supporting structure 4 may be disposed directly below the power module 200. In some embodiments, the power module 200 may overlap the supporting structure (or vent structure) 4 perpendicular to the first surface 21s1 of the circuit structure 21.

Prior to the reflow process, the conductive layer 16 may have gas (or air). The supporting structure 4 may be used to support the downward pressure caused by the power module 200 during the mounting and reflow process. Owing to the supporting structure 4, a distance between the circuit structure 21 and the circuit structure 11 for venting the gas 27 may be kept at least larger than the height H21 of the supporting structure 4 during the reflow process for the conductive layer 16. For example, the distance D12 in FIG. 3A in which the conductive structures 40 are included is greater than the distance D11 in FIG. 1A in which no conductive structures exist.

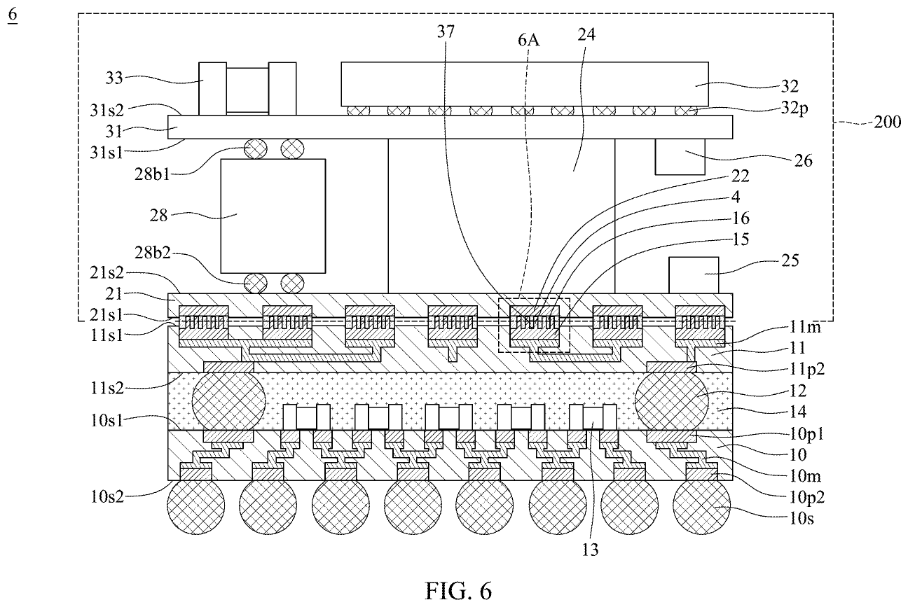

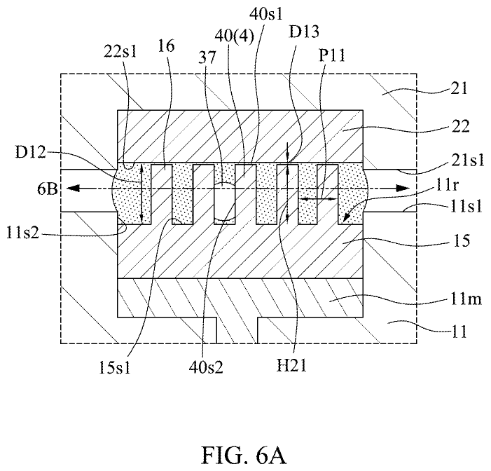

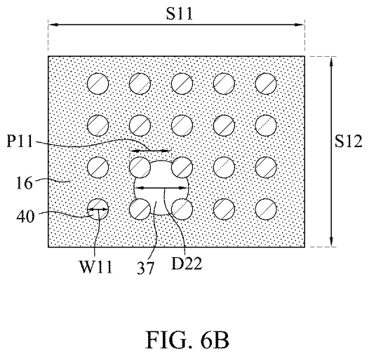

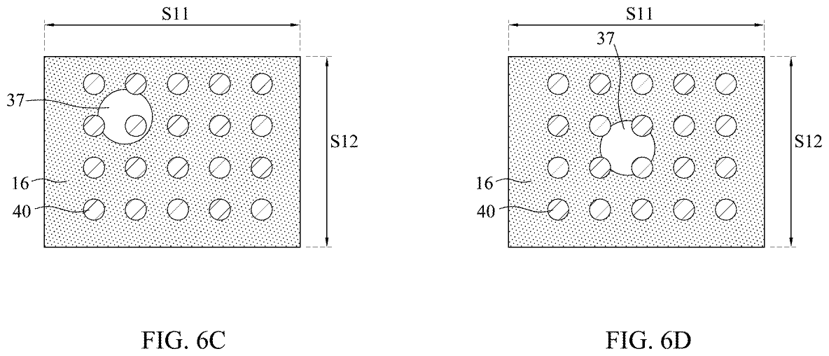

In some cases, an upper circuit structure may carry a module with relatively heavy weight than other devices over the upper circuit structure. During the mounting process of the upper and lower circuit structures and the reflow process of a conductive layer, the distance between the upper and lower circuit structures may be shorten because of the heavy weight of the module. As such, gas is not completely discharged from the conductive layer since there would be insufficient vent paths in the narrow space between upper and lower circuit structures. In the present disclosure, the electronic device 3 include the vent structure 4 (or the conductive structures 40) configured to vent the gas 27 through the plurality of vent paths V1 and V2. The gas 27 can be vented more efficiently through the space SI as shown in FIG. 3B, and there can be no void between the pads 15 and 22 as shown in FIG. 3A or the conductive layer 16 has a relatively small void rate, e.g., less than 25% (will be discussed in FIG. 6). Since the void rate is significantly reduced or eliminated, the resistance of the electrical connection between the pads 15 and 22 (or the circuit structures 11 and 21) can be decreased; in other words, the electrical conductance can be increased and the transmission speed can be improved.

FIG. 3C is another top view of the box 3A in FIG. 3 that reveals the details around the vent structure 4. Some detailed descriptions may refer to corresponding preceding paragraphs of FIG. 3A and are not repeated hereinafter for conciseness, with differences therebetween as follows.

As shown in FIG. 3C, the vent structure 4 further includes a plurality of conductive structures (or a plurality of second conductive structures) 41 that are arranged alternately with the conductive structures 40. In some embodiments, the conductive structures 40 are interleaved with the conductive structures 41. One of the conductive structure 41 may be adjacent to the conductive structures 40. In some embodiments, the conductive structures 40 have a pitch P12 larger than the pitch P11 in FIGS. 3A and 3B. In some embodiments, the distance D13 is smaller than the pitch P12 of the conductive structures 40. The conductive structures 41 are disposed over the pad 15. The conductive structures 41 may be in contact with the pad 15. The conductive structures 41 have a height H22 perpendicular to the surface 15s1 of the pad 15. The height H21 of the conductive structures 40 is greater than the height H22 of the conductive structures 41 with respect to the first circuit structure 11 (or the pad 15).

The conductive structures 41 may include a plurality of conductive pillars. The conductive structures 41 may be formed of metal or a metal alloy. The conductive structures 41 may be metal, such as copper, gold, silver, aluminum, titanium, tantalum, or the like. The electrical conductivity of the conductive structures 41 is greater than that of the conductive layer 16.

The conductive structures 41 have a surface 41s1 facing the pad 22 (or the circuit structure 21). The surface 41s1 may face away from the pad 15 (or the circuit structure 11). The surface 41s1 of the conductive structures 41 is closer to the surface 22s1 of the pad 22 than the surface 15s1 of the pad 15. The surface 41s1 of the conductive structures 41 is spaced apart from the pad 22 by a distance D14. The distance D14 is greater than the distance D13. The surface 41s1 may be covered by the conductive layer 16. In some embodiments, the surface 41s1 may be entirely covered by the conductive layer 16. The surface 41s1 may be in contact with the conductive layer 16. A portion of the conductive layer 16 may be disposed directly above the surface 41s1 or between the surface 41s1 and the surface 22s1. The conductive structures 41 can increase the adhesion between the conductive layer 16 and the venting structure 4. The conductive structures 41 can improve the cohesion of the conductive layer 16 during the reflow process and thus reduce the possibility of the bridging between adjacent portions of the conductive layer 16.

The conductive structures 41 have a sidewall 41s2 extending perpendicular to the surface 15s1 of the pad 15. The sidewalls 41s2 of the conductive structures 41 are surrounded, covered, or encapsulated by the conductive layer 16. The sidewalls 41s2 of the conductive structures 41 are spaced apart from the sidewall 11s3 of the recess 11r.

FIG. 3D is a top view of the line 3D-3D′ in FIG. 3C during the formation of the conductive layer (or the adhesive layer) 16 according to some embodiments of the present disclosure. FIG. 3D illustrates the reflow process of the conductive layer 16. The conductive structures 40 or 41 may be circular in a top view. In some embodiments, the conductive structures 40 or 41 may be rectangular, triangular, or oval in a top view. The conductive structures 41 are depicted with a dashed line to indicate that the conductive structures 41 are covered by the conductive layer 16 in a top view of the line 3D-3D′.

The conductive layer 16 may have gas (or air) 27 when it is formed over the pads 15. The gas 27 may be surrounded by the conductive layer 16. The location of the gas 27 may be random. FIG. 3D illustrates an example in which the gas 27 is located in the center of the conductive layer 16. The conductive structures 40 may define a space S2 configured to vent the gas 27. The conductive structures 40 (or the vent structure 4) may define a plurality of vent paths V1 and V2 which are configured to vent the gas 27 of the conductive layer 16. The vent paths V1 and V2 extend through the space S2 which includes a plurality of gaps 40g between the first conductive structures 40. The vent paths V1 may extend in a direction different from the vent paths V2.

The conductive structures 41 (or the vent structure 4) may define a plurality of further vent paths V3, V4, and V5 which are configured to vent the gas 27 of the conductive layer 16. The vent paths V3, V4, and V5 are directly above the surface 41s1 of the conductive structures 41. The vent paths V3, V4, and V5 extend through the space S2 which includes a plurality of gaps 41g directly above the surfaces 41s1 of the conductive structures 41. At least one of the conductive structures 41 is at least partially within the space S2.

The gas 27 of the conductive layer 16 is directed from a first vicinity of a center portion of the conductive structures 40 to a second vicinity of an edge portion of the conductive structures 40. Owing to the further vent paths V3, V4, and V5, the gas 27 can be more efficiently vented from the conductive layer 16 through the space S2. The vent paths V3 may be between the vent paths V2. The vent paths V4 may be between the vent paths V1. The vent path V5 may extend in a direction different from those of the vent paths V3 and V4. The vent path V5 may extend from the surface 41s1 of a central one of the conductive structures 41 to the surface 41s1 of an edge one of the conductive structures 41.

FIG. 3E is another top view of the box 3A in FIG. 3 that reveals the details around the vent structure 4. Some detailed descriptions may refer to corresponding preceding paragraphs of FIG. 3A and are not repeated hereinafter for conciseness, with differences therebetween as follows.

The vent structure 4 further includes a plurality of (or a plurality of third conductive structures) 42 that are arranged alternately with the conductive structures 40. In some embodiments, the conductive structures 40 are interleaved with the conductive structures 42. One of the conductive structure 42 may be adjacent to the conductive structures 40. The conductive structures 42 are disposed over the pad 15. The conductive structures 42 may be in contact with the pad 15. The conductive structures 42 have a height H23 perpendicular to the surface 15s1 of the pad 15. The height H21 of the conductive structures 40 is substantially the same as the height H23 of the conductive structures 42 with respect to the first circuit structure (or the pad 15).

The conductive structures 42 may include a plurality of conductive pillars. The conductive structures 42 may be formed of metal or a metal alloy. The conductive structures 42 may be metal, such as copper, gold, silver, aluminum, titanium, tantalum, or the like. The electrical conductivity of the conductive structures 42 is greater than that of the conductive layer 16.

The conductive structures 42 have a surface 42s1 facing the pad 22 (or the circuit structure 21). The surface 42s1 may face away from the pad 15 (or the circuit structure 11). The surface 42s1 of the conductive structures 42 is closer to the surface 22s1 of the pad 22 than the surface 15s1 of the pad 15. The surface 42s1 of the conductive structures 42 is spaced apart from the pad 22 by a distance D15, substantially the same as the distance D13. The surface 42s1 may be covered by the conductive layer 16. In some embodiments, the surface 42s1 may be entirely covered by the conductive layer 16. The surface 42s1 may be in contact with the conductive layer 16. A portion of the conductive layer 16 may be disposed directly above the surface 42s1 or between the surface 42s1 and the surface 22s1.

The conductive structures 42 have a sidewall 42s2 extending substantially perpendicular to the surface 15s1 of the pad 15. The sidewalls 42s2 of the conductive structures 42 are surrounded, covered, or encapsulated by the conductive layer 16. The sidewalls 42s2 of the conductive structures 42 are spaced apart from the sidewall 11s3 of the recess 11r.

A first width W11 of the conductive structures 40 is greater than a second width W12 of the conductive structures 42 parallel to the first surface 11s1 of the circuit structure 11. The conductive structures 40 may be configured to support the power module 200 and the conductive structures 42 may be configured to supplement the support strength of the conductive structures 40. In order to have enough support strength, the numbers of the wider conductive structures 40 may be increased, causing the space for venting the gas from the conductive layer 16 being decreased. The narrower conductive structures 42 alternately disposed between the conductive structures 40 can increase the pitch therebetween and provide more space for gas venting. Varied widths of the conductive structures 40 and 42 can vary (for example, enlarge) the pitch of the conductive structures 40 and 42, and thus the vent capacity can be improved.

FIG. 3F is another top view of the box 3A in FIG. 3 that reveals the details around the vent structure 4. Some detailed descriptions may refer to corresponding preceding paragraphs of FIG. 3A and are not repeated hereinafter for conciseness, with differences therebetween as follows.

As shown in FIG. 3F, the conductive structures 40 may extend from the pad 22 and toward the pad 15. The conductive structures 40 may be connected to the pad 22, instead of the pad 15. The conductive structures 40 may be spaced apart from the surface 15s1 of the pad 15 with a distance D23. The conductive structures 40 may extend from the pad 22 may be used to support the power module 200 during the mounting and reflow process and thus provide a space for venting gas from the conductive layer 16.

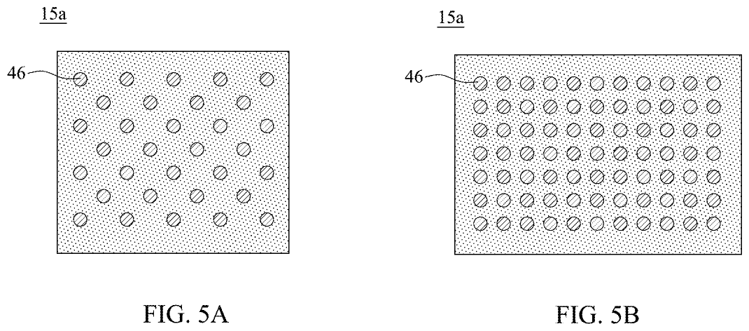

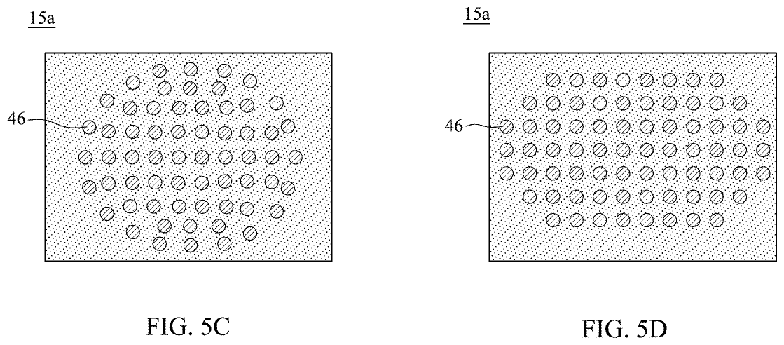

FIG. 5 is a top view of a pad (e.g., the pad 15) of a package structure (e.g., the electronic device 3) according to some embodiments of the present disclosure. FIGS. 5A, 5B, 5C, and 5D each illustrate the arrangement of a plurality of conductive structures 46 in the central portion 15a of the pad 15 of the package structure according to some embodiments of the present disclosure. Some detailed descriptions may refer to corresponding preceding paragraphs and are not repeated hereinafter for conciseness, with differences therebetween as follows.

The plurality of conductive structures 46 may be distributed over a portion (e.g., a central portion) 15a of the pad 15. An area of the central portion 15a is less than or equal to a half of an area of the surface 15s1 of the pad 15 in the top view. The pad 15 has a length S21 and a width S22 in a top view. The conductive structures 46 may be similar to the conductive structures 40.

As shown in FIG. 5A, the conductive structures 46 may be staggered, such that the two closest conductive structures are non-overlapping in a first direction parallel to the length S21 of the pad 15 and a second direction parallel to the length S22 of the pad 15.

As shown in FIG. 5B, the conductive structures 46 may be arranged in a rectangular array. The rectangular array of the present disclosure means that each column/row of the rectangular array has the same number of conductive structures.

As shown in FIG. 5C, the conductive structures 46 may be arranged in a circular array. The circular array of the present disclosure means that the conductive structures 46 at the edge of the circular array define a circular periphery.

As shown in FIG. 5D, the conductive structures 46 may be arranged in an ellipse array. The ellipse array of the present disclosure means that the conductive structures 46 at the edge of the ellipse array define an elliptical periphery.

FIG. 6 is a cross-section of an electronic device 6 according to some embodiments of the present disclosure. The electronic device 6 in FIG. 6 is similar to the electronic device 3 in FIG. 3. Therefore, some detailed descriptions may refer to corresponding preceding paragraphs and are not repeated hereinafter for conciseness, with differences therebetween as follows.

A void 37 may be surrounded by the conductive layer 16 (in particular, a portion of the conductive layer 16 directly below the electronic component 24). The void 37 may include gas (or air). FIG. 6A is an enlarged view of the box 6A in FIG. 6 that reveals the details around the conductive layer 16. Some detailed descriptions may refer to corresponding preceding paragraphs of FIG. 3A and are not repeated hereinafter for conciseness, with differences therebetween as follows.

As shown in FIG. 6A, the void 37 may be disposed between two conductive structures 40. A portion of the conductive structures 40 contacts the void 37. A portion of the sidewall 40s2 may be exposed to the void 37. The sidewall 40s2 may be in contact with the conductive layer (or the adhesive layer) 16 and the void 37. The void 37 may be spaced apart from the pad 15 and/or the pad 22. The surface 15s1 of the pad 15 and/or the surface 22s1 of the pad 22 is free from contacting the void 37. It looks like as if the void 37 is floating between the pad 15 and the pad 22. The void 37 may be disposed between the surface 40s1 of the conductive structures 40 and the surface 15s1 of the pad 15. The void 37 may be lower than the surface 40s1 with respect to the surface 15s1 of the pad 15. The surface 40s1 of the conductive structures 40 is free from contacting the void 37.

FIG. 6B is a top view of the line 6B-6B′ in FIG. 6A according to some embodiments of the present disclosure. The void 37 may have a diameter D22 that may be larger than the width W11 of the conductive structures 40 or the pitch P11 of the conductive structures 40. Four conductive structures 40 may be exposed to the void 37. The void 37 may be located at a middle portion of the conductive layer 16 which is between the edge (e.g., the length S11 or the width S12) and the center portion of the conductive layer 16.

The length S11 and the width S12 may be substantially the same or similar to the length and width of the pad 15. The void rate is defined by the ratio of the area of the void 37 to the area of the pad 15. In the electronic device 6, the void rate of the electronic device 6 (or the conductive layer 16 thereof) is around 25%. Owing to the vent structure 4 (or the conductive structures 40), the void rate of the electronic device 6 is smaller than the void rate of the electronic device 1 in FIG. 1. In some embodiments, the void rate of the electronic device 6 (or the conductive layer 16 thereof) can be 0%, meaning that the void is eliminated. In the electronic device 6, the equivalent resistance of the electrical connection between the pad 15 and the pad 22 can be reduced; in other words, the electrical conductance of the electrical connection between the pad 15 and the pad 22 can be increased and the transmission speed can be improved. Although the void 37 may have high resistance, the size of the void 37 is relatively small and thus the impact of the void 37 to the electrical connection between the pad 15 and the pad 22 can be suppressed. Furthermore, smaller void rate can suppress the explosion of the void in the following thermal process.

FIGS. 6C and 6D are another top view of the line 6B-6B′ in FIG. 6A according to some embodiments of the present disclosure. FIGS. 6C and 6D illustrate the different locations of the void 37.

As shown in FIG. 6C, the void 37 may surround one of the conductive structures 40. The void 37 may be at a middle portion of the conductive layer 16 which is between the edge (e.g., the length S11 or the width S12) and the center portion of the conductive layer 16. The void 37 may be closer to the corner of the conductive layer 16 than to the length S11 or the width S12.

As shown in FIG. 6D, the void 37 may be located at a center portion of the conductive layer 16. The size and the location of the void 37 as shown in FIGS. 6A-6D may be explanatory and would not delimited the present disclosure.

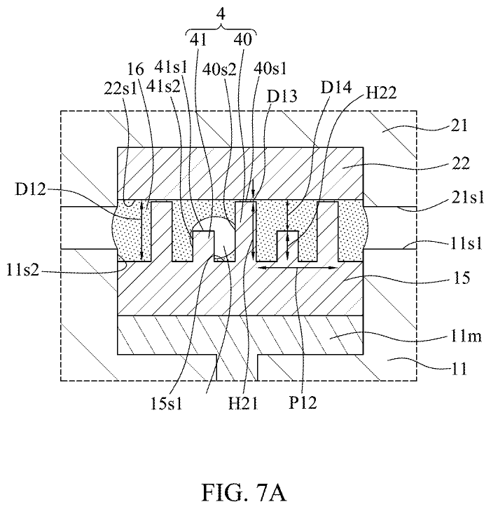

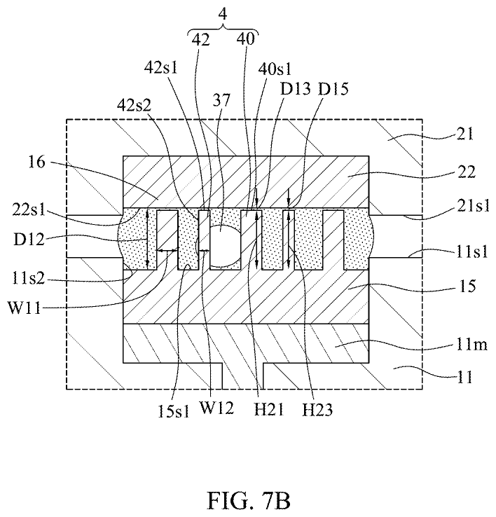

FIG. 7A is another top view of the box 6A in FIG. 6. The vent structure 4 in FIG. 7A may be similar to that in FIG. 3C. Some detailed descriptions may refer to corresponding preceding paragraphs of FIG. 3C and are not repeated hereinafter for conciseness, with differences therebetween as follows.

The void 37 may be disposed between one of the conductive structures 40 and one of the conductive structures 41. A portion of the surface 41s1 of the conductive structures 41 may be exposed to the void 37. The sidewall 41s2 and the sidewall 40s2 may be exposed to the void 37. The sidewall 41s2 and the sidewall 40s2 may be in contact with the void 37.

FIG. 7B is another top view of the box 6A in FIG. 6. The vent structure 4 in FIG. 7B may be similar to that in FIG. 3E. Some detailed descriptions may refer to corresponding preceding paragraphs of FIG. 3E and are not repeated hereinafter for conciseness, with differences therebetween as follows.

The void 37 may be disposed between one of the conductive structures 40 and one of the conductive structures 42. The sidewall 40s2 and the sidewall 42s2 may be exposed to the void 37. The sidewall 40s2 and the sidewall 42s2 may be in contact with the void 37. Said one conductive structure 42 may be surrounded by the void 37.

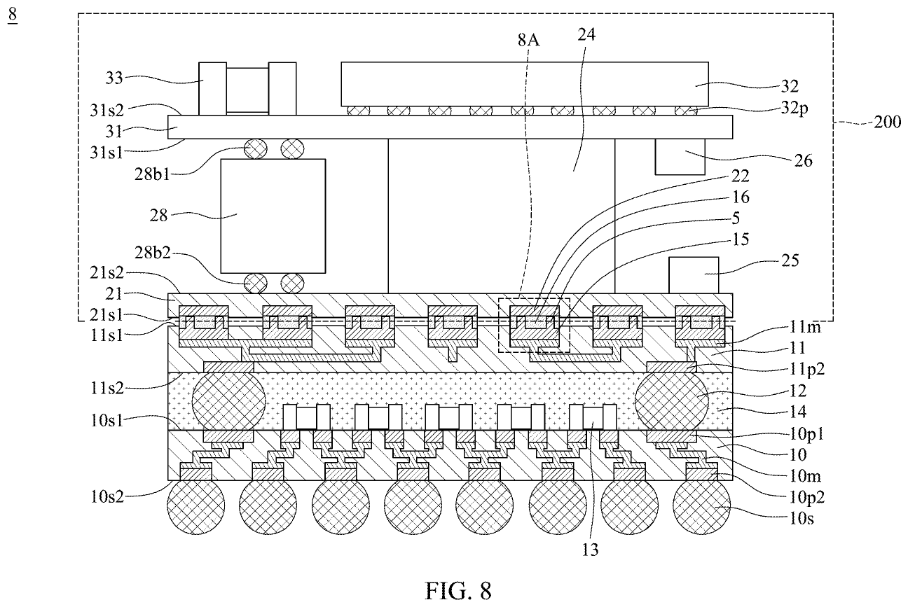

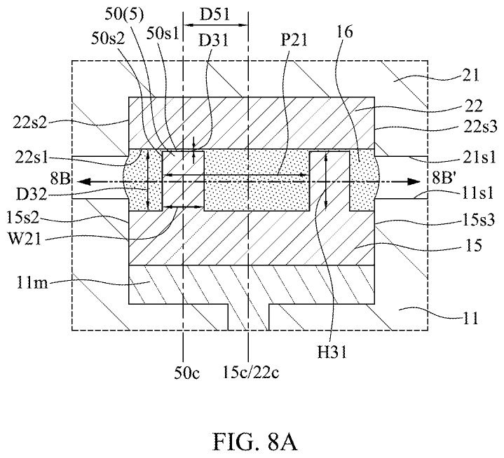

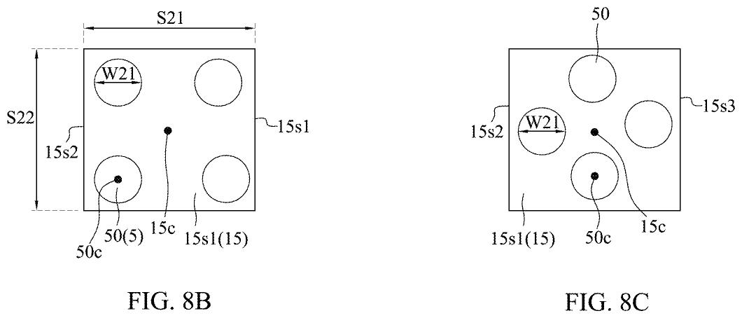

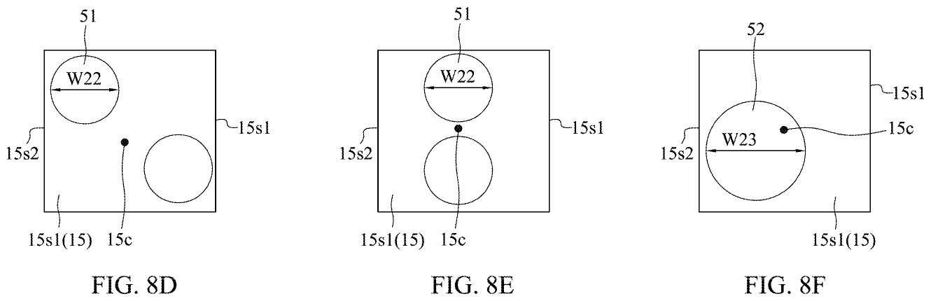

FIG. 8 is a cross-section of an electronic device 8 according to some embodiments of the present disclosure. The electronic device 8 in FIG. 8 is similar to the electronic device 1 in FIG. 1. Therefore, some detailed descriptions may refer to corresponding preceding paragraphs and are not repeated hereinafter for conciseness, with differences therebetween as follows.

As shown in FIG. 8, the electronic device 6 include a vent structure 5 (or a supporting structure or a supporting element) between the pads 15 and the pads 22 or the circuit structure 11 and the circuit structure 21. The vent structure 5 may be connected to the pad 15. The pad 22 may be supported by the vent structure 5. The vent structure 5 may be at least partially covered by the conductive layer 16. The vent structure 5 may be covered, surrounded, encapsulated by the conductive layer 16. FIG. 8A is an enlarged view of the box 8A in FIG. 8 that reveals the details around the vent structure 5.

The vent structure 5 may include a plurality of conductive structures 50. The conductive structures 50 may extend from the pad 15 and toward the pad 22. The conductive structures 50 may be disposed directly above the pad 15. The conductive structures 50 may be disposed directly below the pad 22. The conductive structures 50 is in contact with the pad 15. The conductive structures 50 are spaced apart from the sidewall 11s3 of the recess 11r and/or the sidewall 21s3 of the recess 21r. The conductive structures 50 may be covered, surrounded, or encapsulated by the conductive layer 16.

The conductive structures 50 may include a plurality of pillars. The conductive structures 50 may be formed of metal or a metal alloy. The conductive structures 50 may be metal, such as copper, gold, silver, aluminum, titanium, tantalum, or the like. The electrical conductivity of the conductive structures 50 (or the vent structure 5) is greater than that of the conductive layer 16.

The conductive structures 50 have a surface 50s1 facing the pad 22 (or the circuit structure 21). The surface 50s1 may face away from the pad 15 (or the circuit structure 11). The surface 50s1 of the conductive structures 50 is closer to the surface 22s1 of the pad 22 than the surface 15s1 of the pad 15. The conductive structures 50 have a height H31 perpendicular to the surface 15s1 of the pad 15. The height H31 may be defined by the surface 50s1 of the conductive structures 50 and the surface 15s1 of the pad 15. The conductive structures 50 have a width W21 in the direction parallel to the surface 15s1 of the pad 15. The width W21 may be greater than the height H31.

The surface 50s1 of the conductive structures 50 (or the vent structure 5) is spaced apart from the pad 22. The surface 50s1 is free from contacting the pad 22. The surface 50s1 is not in contact with the pad 22. A distance D31 is defined by the surface 50s1 and the surface 22s1 of the pad 22. The height H31 is greater than the distance D31 between the surface 40s1 and the surface 22s1 of the pad 22. The surface 50s1 may be covered by the conductive layer 16. In some embodiments, the surface 50s1 may be entirely covered by the conductive layer 16. The surface 50s1 may be in contact with the conductive layer 16. A portion of the conductive layer 16 may be disposed directly above the surface 50s1 or between the surface 50s1 and the surface 22s1.

The conductive structures 50 have a sidewall 50s2 extending perpendicular to the surface 15s1 of the pad 15. The sidewalls 50s2 of the conductive structures 50 are surrounded, covered, or encapsulated by the conductive layer 16. The sidewalls 50s2 of the conductive structures 50 are spaced apart from the sidewall 11s3 of the recess 11r.

The surface 15s1 of the pad 15 and the surface 22s1 of the pad 22 define a distance D32 therebetween perpendicular to the surface 15s1 or 22s1. The distance D32 is greater than the height H31 of the conductive structures 50 (or vent structure 5). The distance D32 is greater than the distance D11 in FIG. 1A. The height H31 is greater than a half of the distance D32.

The conductive structures 50 of the vent structure 5 have the height H31 greater than the distance D31 between the surface 50s1 and the pad 22. The height H31 is greater than a half of the distance D32 between the pads 15 and 22. With this size design, the vent structure 5 may be referred to as a supporting structure that is configured to support the relative heavy power module 200 in FIG. 8. The supporting structure 5 may be disposed directly below the electronic component 24. In some embodiments, the electronic component 24 may overlap the supporting structure (or the vent structure) 5 perpendicular to the first surface 21s1 of the circuit structure 21.

FIG. 8B is a top view of the line 8B-8B′ in FIG. 8A according to some embodiments of the present disclosure. The conductive layer 16 is omitted for the explanation of the relationship between the pad 15 and the supporting structure 5. A surface area of the supporting structure 5 (or all of the conductive structures) is more than around 30% of that of the surface 15s1 of the pad 15 in a top view as shown in FIG. 8B. The surface area of the supporting structure 5 may be around 35%, 40%, 45%, 50% or more of that of the surface 15s1 of the pad 15 in a top view.

In the mounting process for the electronic device 8, the conductive layer 16 may be pressed between the circuit structure 11 and the circuit structure 21. In the reflow process, the conductive layer 16 may flow in a molten state to redistribute between the pads 22 and 15. The conductive layer 16 below the power module 200 may experience a high amount of pressure. With the design of the ratio of the surface area of the supporting structure 5 to the surface area of the pad 15, the supporting structure 5 is configured to support the power module 200 during the mounting process and reflow process of the conductive layer 16. As such, the decrement of the height of the conductive layer 16 during the mounting process and reflow process can be suppressed.

Referring back to FIG. 8A, the pad 15 has a center 15c in a cross-sectional view. The center 15c may be defined as a centerline of the pad 15 that is equidistant from lateral surfaces 15s2 and 15s3 of the pad 15. The pad 22 has a center 22c. The center 22c may be defined as a centerline of the pad 22 that is equidistant from lateral surfaces 22s2 and 22s3 of the pad 22. The center 15c of the pad 15 may be substantially aligned with the center 22c of the pad 22 perpendicular to the surface 15s1 or in a cross-sectional view.

In the cross-sectional view, the location of each of the conductive structures 50 is offset from the center 15c of the pad 15 in the direction parallel to the surface 15s1 of the pad 15. Each of the conductive structures 50 (or the supporting structure 5) has a center 50c. The center 50c may be defined as a centerline of the conductive structure 50 that is equidistant from the opposite sidewalls 50s2 of the conductive structure 50. The center 50c of the conductive structure 50 (or the supporting structure 5) may be separated from the center 15c of the pad 15 with a first displacement D51 parallel to the surface 15s1 of the pad 15. The conductive structures 50 have a pitch P21 greater than the first displacement D51. The center 50c may be non-overlapping with the center 15c.

As shown in FIG. 8B, the pad 15 has the center 15c in the top view. The conductive structures 50 are disposed closer to the lateral surface 15s2 and 15s3 of the pad 15 than to the center 15c. The conductive structures 50 are located at the corners of the pad 15. The locations of the conductive structures 50 may facilitate the venting of the air in the conductive layer 16 during the reflow process. In the top view, the center 50c of the conductive structures 50 is offset from the center 15c of the pad 15.

FIGS. 8C, 8D, 8E, and 8F are each other top views of the line 8B-8B′ in FIG. 8A according to some embodiments of the present disclosure.

As shown in FIG. 8C, the conductive structures 50 are disposed closer to the lateral surface 15s2 and 15s3 of the pad 15 than to the center 15c. The conductive structures 50 are located at the edges of the pad 15.

As shown in FIG. 8D, the conductive structures 51 are disposed closer to the lateral surface 15s2 and 15s3 of the pad 15 than to the center 15c. The conductive structures 51 are located at the corners of the pad 15. The numbers of the conductive structures 51 in FIG. 8D is smaller than those in FIG. 8B. The conductive structure 51 in FIG. 8D have a width W22 which is greater than W21 of the conductive structure 50 in FIGS. 8A-8C. The ratio of the surface area of the conductive structure 51 to the surface area of the pad 15 in FIG. 8D retains to substantially the same extent as that of FIG. 8B. As such, the design of the conductive structures 51 in FIG. 8D can support the relative heavy power module 200 during the reflow process of the conductive layer 16.

As shown in FIG. 8E, the conductive structures 51 are disposed closer to the lateral surface 15s2 and 15s3 of the pad 15 than to the center 15c. The conductive structures 51 are located at the edges of the pad 15. The numbers of the conductive structures 51 in FIG. 8D is smaller than those in FIG. 8B. The ratio of the surface area of the conductive structure 51 to the surface area of the pad 15 in FIG. 8E retain to substantially the same extent as that of FIG. 8B.

As shown in FIG. 8F, only one conductive structure 52 is disposed closer to the lateral surface 15s2 and 15s3 of the pad 15 than to the center 15c. The conductive structure 52 are located at the corner of the pad 15. The conductive structure 52 in FIG. 8F have a width W23 which is greater than W22 of the conductive structure 51 in FIGS. 8D and 8E. The ratio of the surface area of the conductive structure 52 to the surface area of the pad 15 in FIG. 8F retain to substantially the same extent as that of FIG. 8D. As such, the design of the conductive structure 52 in FIG. 8F can support the relative heavy power module 200 during the reflow process of the conductive layer 16.

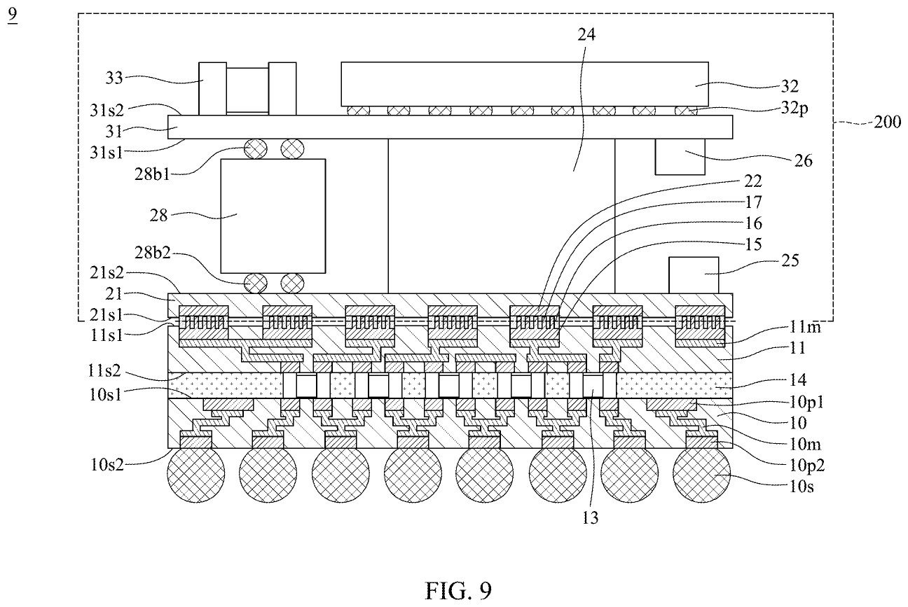

FIG. 9 is a cross-section of an electronic device 9 according to some embodiments of the present disclosure. The electronic device 9 in FIG. 9 is similar to the electronic device 3 in FIG. 3. Therefore, some detailed descriptions may refer to corresponding preceding paragraphs and are not repeated hereinafter for conciseness, with differences therebetween as follows.

The electronic components 13 may be electrically connected to the traces 11m of the circuit structure 11. The circuit structure 10 may be electrically connected to the circuit structure 11 through the electronic components 13. The electronic components 13 may be connected to the traces 11m and/or the pads 10p1 through a solder paste. The electronic device 9 may exclude the electrical elements 12 of the electronic device 3 of FIG. 3.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first circuit structure;
a second circuit structure;
a conductive layer disposed between the first circuit structure and the second circuit structure; and
a supporting structure at least partially covered by the conductive layer and defining a space configured to vent gas.

2. The electronic device of claim 1, wherein the supporting structure comprises a plurality of first conductive structures defining a plurality of first vent paths therebetween.

3. The electronic device of claim 2, wherein the first vent paths extend through a plurality of first gaps between the first conductive structures.

4. The electronic device of claim 3, wherein the supporting structure comprises a second conductive structure adjacent to the first conductive structures, and wherein a first height of the first conductive structures is greater than a second height of the second conductive structure with respect to the first circuit structure.

5. The electronic device of claim 4, wherein the second conductive structure is at least partially within the space.

6. The electronic device of claim 2, wherein the supporting structure has a third conductive structure adjacent to the first conductive structures, and wherein a first width of the first conductive structures is greater than a second width of the third conductive structure.

7. The electronic device of claim 6, wherein a first height of the first conductive structures and a third height of the third conductive structure are substantially the same with respect to the first circuit structure.

8. The electronic device of claim 1, wherein the supporting structure is configured to reduce a void rate of the conductive layer, wherein the void rate is an area of the gas to an area of the conductive layer in a top view.

9. The electronic device of claim 1, wherein the electrical conductivity of the supporting structure is greater than that of the conductive layer.

10. The electronic device of claim 1, further comprising a package structure, wherein the package structure comprises a third circuit structure, an interposer, the second circuit structure connected to the third circuit structure through the interposer, and a plurality of first electronic components disposed between second circuit structure and the third circuit structure.

11. The electronic device of claim 10, further comprising a fourth circuit structure disposed under the first circuit structure and a plurality of electrical elements connected to the first circuit structure and the fourth circuit structure.

12. The electronic device of claim 11, further comprising a plurality of second electronic components disposed between the first circuit structure and the fourth circuit structure, wherein the second electronic components are electrically connected to the first electronic components through the electrical elements.

13. An electronic device, comprising:
a first pad;
1 a second pad disposed over the first pad; and
1 a plurality of first conductive structures extending from the first pad and toward the second pad, wherein at least one of the plurality of first conductive structures has a height greater than a distance between the at least one of the plurality of first conductive structures and the second pad.

14. The electronic device of claim 13, further comprising a conductive layer connected to the first pad and the second pad.

15. The electronic device of claim 14, wherein the first conductive structures are spaced apart from the second pad.

16. The electronic device of claim 14, wherein the first conductive structures comprise a plurality of conductive pillars, and the distance is smaller than a pitch of the conductive pillars.

17. The electronic device of claim 14, wherein the first conductive structures are distributed over a central portion of the first pad, and wherein an area of the central portion is less than or equal to a half of an area of the first pad in a top view.

18. The electronic device of claim 14, further comprising a first circuit structure having a recess accommodating the first pad, wherein the recess has a sidewall spaced apart from the first conductive structures.

19. An electronic device, comprising:
a first pad having a first center;
a supporting element connected to the first pad and having a second center non-overlapping with the first center; and
a second pad supported by the supporting element and electrically connected to the first pad.

20. The electronic device of claim 19, wherein the second pad has a third center substantially aligned with the first center in a cross-sectional view.
